(19) United States
(12) Patent Application Publication
(10) Pub. No.: US 2017/0279449 A1
(43) Pub. Date: Sep. 28, 2017

(54) Single-Chip High Speed and High Voltage Level Shifter

(71) Applicant: Infineon Technologies Americas Corp., EL Segundo, CA (US)

(72) Inventors: Min Fang, Manhattan Beach, CA (US); Niraj Ranjan, El Segundo, CA (US); Siddharth Kiyawat, Kensington, CA (US); Donald He, Redondo Beach, CA (US); Praveen Kumar Kalsani, Marina Del Rey, CA (US)

(21) Appl. No.: 15/080,928

(22) Filed: Mar. 25, 2016

(51) Int. Cl. H03K 19/0175; H01L 27/06; H01L 29/06

(52) U.S. Cl. CPC H03K 19/017509; H01L 29/0649; H01L 29/063; H01L 27/0676

(57) ABSTRACT

A semiconductor device includes a low voltage region, a high voltage region monolithically integrated with the low voltage region in a semiconductor substrate, where the low voltage region is electrically coupled to the high voltage region through a capacitive isolation barrier, where the high voltage region is structurally isolated from the low voltage region by an isolation structure. The isolation structure includes a junction termination structure, a deep trench structure, or a reduced surface field (RESURF) structure. The isolation structure forms an isolation ring substantially enclosing the high voltage region in the semiconductor substrate. The low voltage region is configured to provide a differential signal to the high voltage region through the capacitive isolation barrier. The high voltage region is configured to receive a differential signal from the low voltage region through the capacitive isolation barrier so as to level shift the differential signal.

### BACKGROUND

Level shifters can be utilized to convert an input signal to an output signal between circuits that are referenced to different voltages. One or more isolation barriers can provide galvanic isolation between the circuits. Exemplary approaches to galvanic isolation can be based on electromagnetic waves, and optical, acoustic, and mechanical means to exchange energy between the circuits.

Conventionally, a high voltage level shifting scheme can be achieved through methods, such as opto coupler, high voltage junction isolation and isolation transformer, where a low voltage circuit and a high voltage circuit are formed on separate semiconductor chips to ensure the reliability of the level shifter due to the large voltage difference between the low and high voltage circuits. Thus, conventional high voltage level shifting schemes suffer from high voltage common mode transient (CMT) dv/dt noise, long propagation delay, high power dissipation, limited switching speed, and multi-chip packaging complexity.

Thus, there is a need to overcome the drawbacks and deficiencies in the art by providing a single-chip high speed and high voltage level shifter with substantially reduced common mode transient (CMT) dv/dt noise, power dissipation, and propagation delay.

### SUMMARY

The present disclosure is directed to a single-chip high speed and high voltage level shifter, substantially as shown in and/or described in connection with at least one of the figures, and as set forth in the claims.

### BRIEF DESCRIPTION OF THE DRAWINGS

FIG. 1A illustrates an exemplary system including a level shifter according to one implementation of the present application.

FIG. 1B illustrates a diagram of an exemplary single-chip level shifter according to one implementation of the present application.

FIG. 1C illustrates a diagram of an exemplary single-chip level shifter according to one implementation of the present application.

FIG. 2A illustrates a diagram of an exemplary single-chip level shifter having a capacitive isolation barrier according to one implementation of the present application.

FIG. 2B illustrates a diagram of an exemplary single-chip level shifter having a capacitive isolation barrier according to one implementation of the present application.

FIG. 2C illustrates a diagram of an exemplary single-chip level shifter having a capacitive isolation barrier according to one implementation of the present application.

FIG. 2D illustrates a diagram of an exemplary single-chip level shifter having a capacitive isolation barrier according to one implementation of the present application.

FIG. 3A illustrates a portion of an exemplary single-chip level shifter having an isolation structure according to one implementation of the present application.

FIG. 3B illustrates a portion of an exemplary single-chip level shifter having an isolation structure according to one implementation of the present application.

FIG. 3C illustrates a portion of an exemplary single-chip level shifter having an isolation structure according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

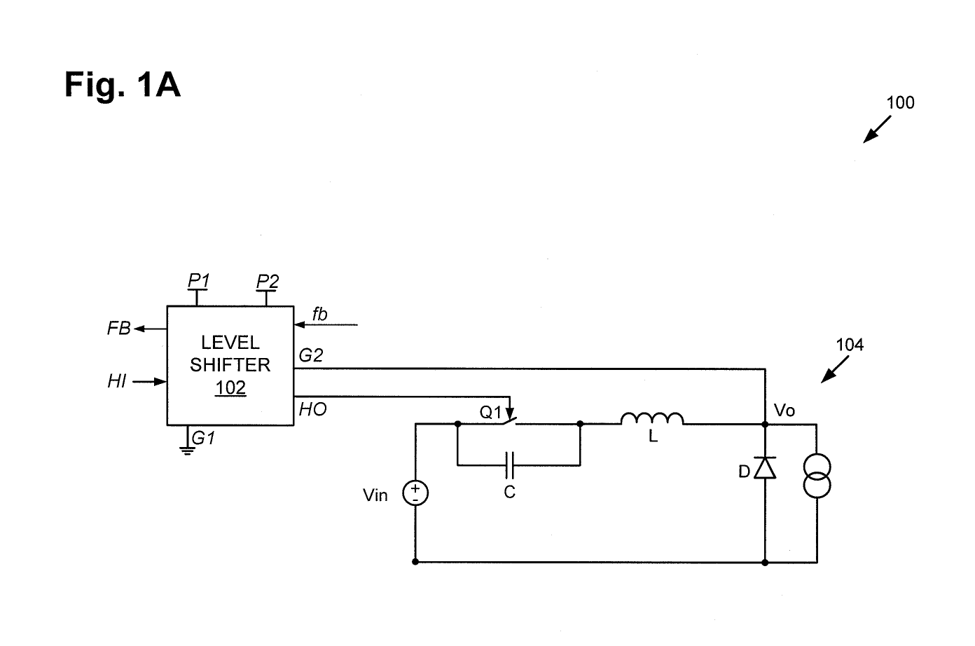

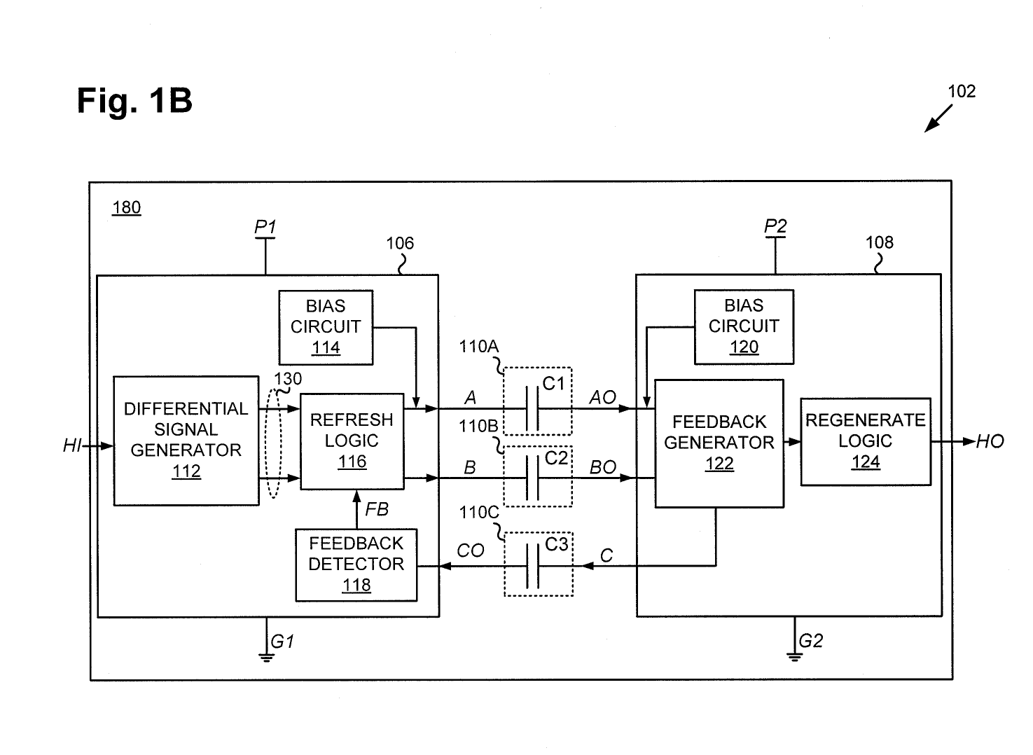

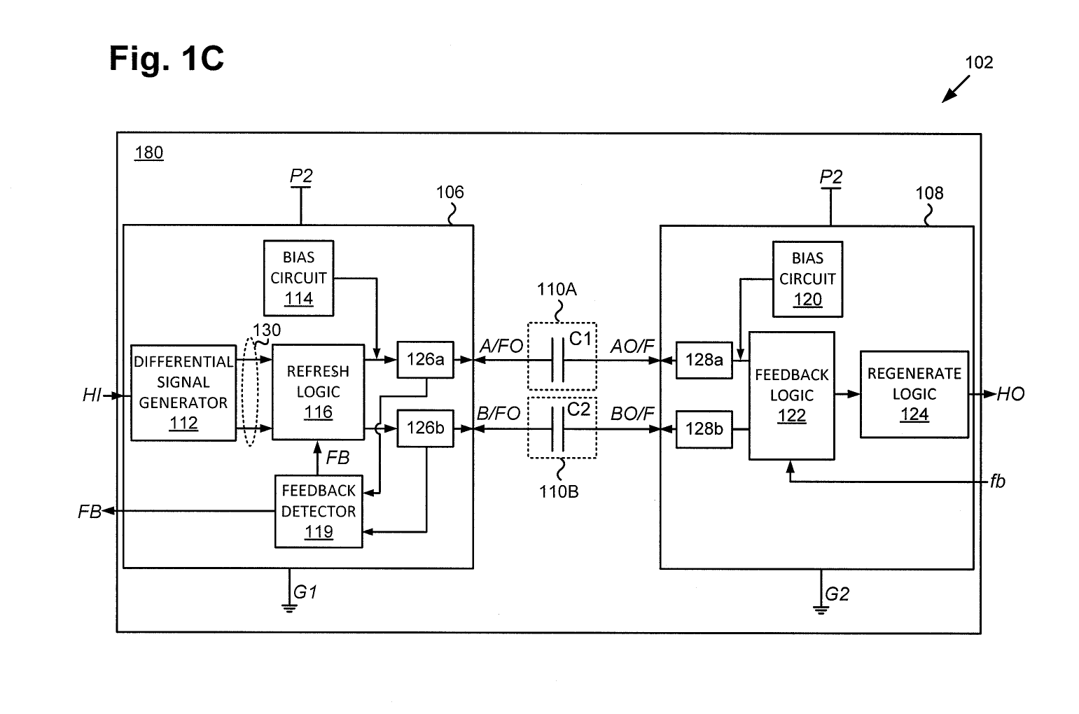

Referring now to FIG. 1A, FIG. 1A illustrates an exemplary system including a level shifter according to one implementation of the present application. As illustrated in FIG. 1A, system 100 includes level shifter 102 and power supply 104. Power supply 104 is a switched mode power supply including input voltage Vin, capacitor C, inductor L, diode D, and power switch Q1.

In the present implementation, level shifter 102 is a single-chip level shifter configured to level shift input signal HI to output signal HO. Output signal HO can be referenced to a different ground than input signal HI, such that output signal HO is suitable for driving power switch Q1. As shown in FIG. 1A, input signal HI corresponds to a control signal for power switch Q1 of power supply 104, which is level shifted to output signal HO so as to properly control power switch Q1.

In system 100, input signal HI and output voltage Vo can be, for example, thousands of volts apart. As such, level shifter 102 can be at substantial risk for exposure to noise, which can interfere with the accuracy of level shifter 102. For example, high voltage switching in power supply 104 can introduce common mode noise in level shifter 102. Certain common mode noise in system 100 can be synchronous common mode noise that coincides with input signal HI switching power switch Q1 (or multiple power switches and/or multiple input signals in other power supply topologies). However, other common mode noise in system 100 can be asynchronous common mode noise that does not necessarily coincide with input signal HI switching power switch Q1.

By way of more specific example, asynchronous common mode noise in system 100 may occur in zero voltage switching during OFF time of power switch Q1. During this time, an LC tank formed by capacitor C and inductor L can resonate, and reactivate power switch Q1 causing asynchronous common mode noise. As another example, power supply 104 may include a half-bridge for switching power (e.g. comprising microelectromechanical systems (MEMS) switches) in, for example, a plasma display panel (PDP). In this example, asynchronous common mode noise may result from switching of auxiliary switches that are coupled to the half-bridge.

It should be noted that system 100 includes power supply 104 as an example, which may instead correspond to another circuit receiving output signal HO. Thus, power supply 104 could instead be a circuit that is not a power supply and may more generally correspond to a circuit receiving output signal HO from level shifter 102, and conducive to causing common mode noise in level shifter 102.

Common mode noise in system 100 can interfere with the ability of level shifter 102 to accurately level shift input signal HI to output signal HO resulting in distortion in output signal HO. The distortion can cause misfire of power switch Q1 or other circuitry being controlled utilizing output signal HO. As such, common mode noise in system 100, and especially asynchronous common mode noise, can cause disruption, loss of functionality, and damage to system 100.

System 100 includes feedback signal FB, where output signal HO can be provided based on feedback signal FB. Feedback signal FB can be from level shifter 102 and/or power supply 104 (or a different circuit receiving output signal HO). As shown in FIG. 1A, in some implementations, level shifter 102 includes feedback input fb, which can be from power supply 104. Feedback signal FB can be from feedback input fb, but may additionally or instead be from within level shifter 102. Furthermore, feedback signal FB may be utilized within level shifter 102, but may additionally or instead be used external to level shifter 102. As such, in some implementations, level shifter 102 is configured to provide feedback signal FB as an output as shown in FIG. 1A. Level shifter 102 can thereby be configured to provide feedback signal FB to a microcontroller (not explicitly shown in FIG. 1A) or other circuity. The microcontroller or other circuity can generate input signal HI based on feedback signal FB.

Feedback signal FB may be from feedback referenced to ground G2. However, it may be desirable for feedback signal FB to be referenced to a different ground, such as ground G1. By providing for feedback signal FB in level shifter 102, system 100 can substantially reduce CMT dv/dt noise, and lower manufacturing costs and the overall footprint, amongst other advantages.

Referring now to FIG. 1B, FIG. 1B illustrates a diagram of an exemplary single-chip level shifter according to one implementation of the present application. In FIG. 1B, level shifter 102 may correspond to level shifter 102 in FIG. 1A. FIG. 1B shows that level shifter 102 includes low voltage circuit 106, high voltage circuit 108, and capacitive isolation barriers 110A, 110B, and 110C, which are monolithically integrated on semiconductor substrate 180. Thus, level shifter 102 is a single-chip level shifter configured to level shift input HI to output HO at high voltage and high speed. Additionally, level shifter 102 is configured to perform signal refresh flow and CMT dv/dt noise detection and cancellation.

As illustrated in FIG. 1B, low voltage circuit 106 includes differential signal generator 112, bias circuit 114, refresh logic 116, and feedback detector 118. High voltage circuit 108 includes bias circuit 120, feedback generator 122, and regenerate logic 124. Capacitive isolation barrier 110A includes at least capacitor C1, capacitive isolation barrier 110B includes at least capacitor C2, and capacitive isolation barrier 110C includes at least capacitor C3.

In level shifter 102, low voltage circuit 106 is coupled to power P1 and is referenced to ground G1. High voltage circuit 108 is coupled to power P2 and is referenced to ground G2. In another implementation, high voltage circuit 108 is coupled to power P2 and is floating in a high voltage well formed in an isolation structure (not explicitly shown in FIG. 1B) in semiconductor substrate 180. In yet another implementation, high voltage circuit 108 is coupled to power P2 and referenced to ground G1. Low voltage circuit 106 is configured to provide differential signal 130 to high voltage circuit 108. As shown in FIG. 1B, differential signal generator 112 receives input signal HI and generates differential signal 130 from input signal HI. Refresh logic 116 provides differential signal 130 to capacitive isolation barriers 110A and 110B as complementary signals A and B utilizing bias circuit 114 and feedback detector 118.

High voltage circuit 108 is configured to receive differential signal 130 from low voltage circuit 106 so as to level shift differential signal 130 with reference to ground G1 of low voltage circuit 106 to a level shifted differential signal, for example, with reference to ground G2 of high voltage circuit 108. As shown in FIG. 1B, capacitive isolation barriers 110A and 110B galvanically isolate low voltage circuit 106 from high voltage circuit 108 in converting complementary signals A and B to complementary signals AO and BO utilizing bias circuit 120. It is noted that the differential nature of differential signal 130 is manifested, for example, in complimentary signals A and B and in complementary signals AO and BO.

In the present implementation, differential signal 130 is provided by low voltage circuit 106 responsive to feedback signal FB from high voltage circuit 108. As such, in some implementations, low voltage circuit 106 can adjust complementary signals A and B based on feedback signal FB. In FIG. 1B, low voltage circuit 106 is configured to receive feedback signal FB from high voltage circuit 108 while capacitive isolation barrier 110C is galvanically isolating low voltage circuit 106 and high voltage circuit 108. Feedback signal FB is provided by feedback generator 122 of high voltage circuit 108 in FIG. 1B. However, high voltage circuit 108 may provide feedback signal FB to low voltage circuit 106 from a source external to high voltage circuit 108, such as power supply 104 in FIG. 1A.

In the present implementation, feedback signal FB is provided by high voltage circuit 108 through capacitive isolation barrier 110C, which is a dedicated capacitive isolation barrier. In other implementations, feedback signal FB is provided by high voltage circuit 108 through at least one shared capacitive isolation barrier that is also utilized for other signals. For example, feedback signal FB and differential signal 130 can be communicated through at least one shared capacitive isolation barrier. More particularly, feedback signal FB can be provided by high voltage circuit 108 through at least one of capacitive isolation barriers 110A and 110B, which are also utilized for complementary signals A and B, respectively. In these implementations, capacitive isolation barrier 110C may be optional. For example, level shifter 102 can employ any of various bi-directional transmission techniques, as discussed in detail below.

Referring now to FIG. 1C, FIG. 1C illustrates a diagram of an exemplary single-chip level shifter according to one implementation of the present application. In FIG. 1C, level shifter 102 may correspond to level shifter 102 in FIG. 1A. Level shifter 102 includes low voltage circuit 106, high voltage circuit 108, and capacitive isolation barriers 110A and 110B, which are monolithically integrated on semiconductor substrate 180. Thus, level shifter 102 is a single-chip level shifter configured to level shift input HI to output HO at high voltage and high speed. Additionally, level shifter 102 is configured to perform signal refresh flow and CMT dv/dt noise detection and cancellation by using bi-directional signaling through capacitive isolation barriers 110A and/or 110B, for example.

As illustrated in FIG. 1C, low voltage circuit 106 includes differential signal generator 112, bias circuit 114, refresh logic 116, feedback detector 119, and variable impedance drivers 126a and 126b. High voltage circuit 108 includes bias circuit 120, feedback logic 123, regenerate logic 124, and variable impedance drivers 128a and 128b. Capacitive isolation barrier 110A includes at least one capacitor C1 and capacitive isolation barrier 110B includes at least one capacitor C2.

In level shifter 102, low voltage circuit 106 is coupled to power P1 and is referenced to ground G1. High voltage circuit 108 is coupled to power P2 and is referenced to ground G2. In another implementation, high voltage circuit 108 is coupled to power P2 and is floating in a high voltage well formed in an isolation structure (not explicitly shown in FIG. 1B) in semiconductor substrate 180. In yet another implementation, high voltage circuit 108 is coupled to power P2 and referenced to ground G1. Low voltage circuit 106 is configured to provide differential signal 130 to high voltage circuit 108. As shown in FIG. 1C, differential signal generator 112 receives input signal HI and generates differential signal 130 from input signal HI. Refresh logic 116 provides differential signal 130 to capacitive isolation barriers 110A and 110B as complementary signals A and B utilizing bias circuit 114, feedback detector 119, and variable impedance drivers 126a and 126b.

High voltage circuit 108 is configured to receive differential signal 130 from low voltage circuit 106 so as to level shift differential signal 130 with reference to ground G1 of low voltage circuit 106 to a level shifted differential signal, for example, with reference to ground G2 of high voltage circuit 108. As shown in FIG. 1C, capacitive isolation barriers 110A and 110B galvanically isolate low voltage circuit 106 from high voltage circuit 108 in converting complementary signals A and B to complementary signals AO and BO utilizing bias circuit 120. It is noted that the differential nature of differential signal 130 is manifested, for example, in complimentary signals A and B and in complementary signals AO and BO.

In FIG. 1C, high voltage circuit 108 is configured to provide feedback signal FB to low voltage circuit 106 through capacitive isolation barriers 110A and/or 110B. Thus, capacitive isolation barriers 110A and/or 110B can be utilized for bi-directional signaling in level shifter 102. For example, capacitive isolation barrier 110A galvanically isolates low voltage circuit 106 from high voltage circuit 108 in converting feedback F to feedback FO. Also, capacitive isolation barrier 110B galvanically isolates low voltage circuit 106 from high voltage circuit 108 in converting feedback F to feedback FO. By utilizing bi-directional signaling, level shifter 102 can reduce the number of capacitive isolation barriers (e.g., capacitive isolation barrier 110C in FIG. 1B) for feedback signal FB, thereby substantially lowering cost as well as the footprint of level shifter 102. Also, by providing for feedback signal FB in level shifter 102, system 100 can substantially reduce CMT dv/dt noise, amongst other advantages.

In some implementations, differential signal 130 is provided by low voltage circuit 106 responsive to feedback signal FB from high voltage circuit 108. As such, low voltage circuit 106 can adjust complementary signals A and B based on feedback signal FB, for example, to reduce CMT dv/dt noise. Additionally or instead, input signal HI can be provided responsive to feedback signal FB. As shown in FIG. 1C, level shifter 102 provides feedback signal FB as an output. Thus, a mircocontroller and/or other external circuitry (not explicitly shown in FIG. 1A) can receive feedback signal FB. Furthermore, the microcontroller and/or other external circuitry can provide input signal HI to level shifter 102 based on feedback signal FB.

In various implementations, feedback signal FB may indicate any combination of common mode noise, over current, over temperate, and/or over voltage conditions of high voltage circuit 108 and/or power supply 104. Feedback logic 123 in high voltage circuit 108 can be configured to detect feedback from feedback input fb. Thus, high voltage circuit 108 can be configured to provide feedback signal FB to low voltage circuit 106 from an input of high voltage circuit 108. However, feedback logic 123 may instead or in addition be configured to detect feedback from within level shifter 102. For example, feedback logic 123 in high voltage circuit 108 can include a feedback generator for providing feedback signal FB to low voltage circuit 106.

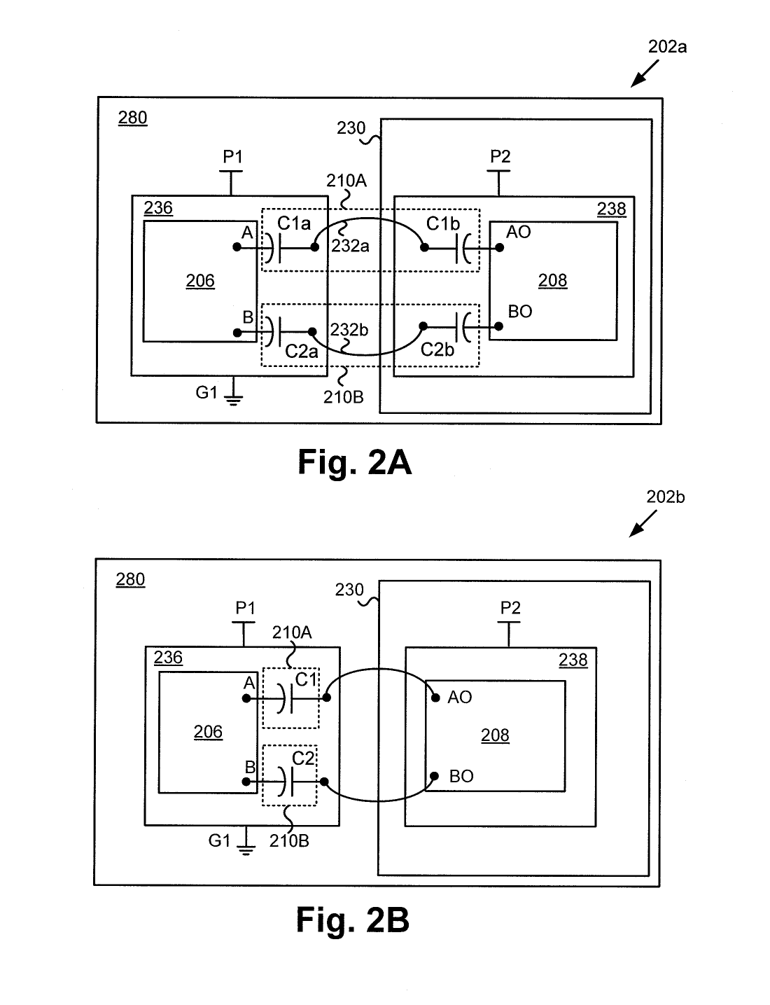

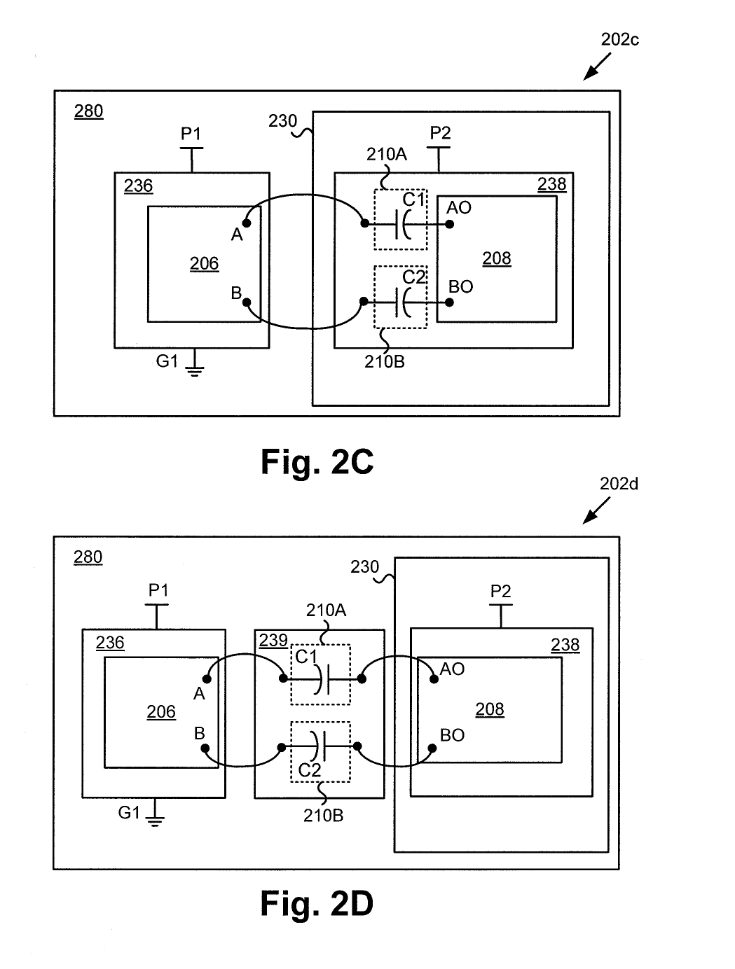

Referring to FIGS. 2A, 2B, 2C, and 2D, FIGS. 2A, 2B, 2C, and 2D illustrate diagrams of single-chip level shifters having a capacitive isolation barrier according to implementations of the present application. In FIGS. 2A, 2B, 2C, and 2D, respective level shifters 202a, 202b, 202c, and 202d may correspond to level shifter 102 in FIG. 1A, 1B or 1C. Level shifters 202a, 202b, 202c, and 202d each include low voltage circuit 206 corresponding to low voltage circuit 106 in FIG. 1B or 1C, and high voltage circuit 208 corresponding to high voltage circuit 108 in FIG. 1B or 1C. Also, in FIGS. 2A, 2B, 2C, and 2D, capacitive isolation barriers 210A and 210B may correspond respectively to capacitive isolation barriers 110A and 110B in FIG. 1B or 1C. While FIGS. 2A, 2B, 2C, and 2D do not show an element corresponding to capacitive isolation barrier 110C in FIG. 1B, in some implementations a similar element is included and can be configured similar to capacitive isolation barriers 210A and 210B or can be configured otherwise.

In FIGS. 2A, 2B, 2C, and 2D, low voltage circuit 206 is in low voltage region 236 and high voltage circuit 208 is in high voltage region 238, where low voltage region 236 is monolithically integrated with high voltage region 238 in semiconductor substrate 280, and where high voltage region 238 is structurally isolated from low voltage region 236 by isolation structure 230. Low voltage region 236 is coupled between power P1 and ground G1, and high voltage region 238 is coupled to power P2 and floating in a high voltage well inside isolation structure 230 with reference to ground G1. In another implementation, high voltage region 238 is coupled to power P2 and referenced to ground G1, for example.

FIGS. 2A, 2B, 2C, and 2D illustrate exemplary configurations that may be utilized for capacitive isolation barriers in level shifters in accordance with implementations of the present application. Various approaches may be employed so as to achieve proper capacitance for the capacitive isolation barriers.

As illustrated in FIG. 2A, capacitive isolation barrier 210A includes capacitors C1a and C1b corresponding to capacitor C1 in FIG. 1B or 1C. Capacitive isolation barrier 210B includes capacitors C2a and C2b corresponding to capacitor C2 in FIG. 1B or 1C. Capacitors C1a and C2a are in low voltage region 236, while capacitors C1b and C2b are in high voltage region 238. Splitting up capacitive isolation barriers 210A and 210B, as shown in FIG. 2A, by including capacitors in series can simplify manufacturing of capacitive isolation barriers 210A and 210B. As shown in FIG. 2A, capacitors C1a and C1b can be coupled to one another utilizing one or more bond wires 232a. Capacitors C2a and C2b can be coupled to one another utilizing one or more bond wires 232b.

In some implementations, capacitive isolation barriers 210A and 210B can be completely in either of low voltage region 236 and high voltage region 238. For example, as illustrated in FIG. 2B, capacitive isolation barriers 210A and 210B are completely in low voltage region 236 and outside of isolation structure 230. As illustrated in FIG. 2C, capacitive isolation barriers 210A and 210B are completely in high voltage region 238 and within isolation structure 230. In other implementations, one of capacitive isolation barriers 210A and 210B is completely in low voltage region 236 and the other one of capacitive isolation barriers 210A and 210B is completely in high voltage region 238.

In one implementation, capacitive isolation barriers 210A and 210B are at least partially in isolation barrier region 239 on semiconductor substrate 280. As illustrated in FIG. 2D, capacitive isolation barriers 210A and 210B can be completely in isolation barrier region 239. In other implementations, capacitive isolation barriers 210A and 210B may be distributed across isolation barrier region 239 and any of low voltage region 236 and high voltage region 238. As illustrated in FIG. 2D, various bond wires may be utilized to couple capacitive isolation barriers 210A and 210B in isolation barrier region 239 to low voltage region 236 and high voltage region 238.

By monolithically integrating low voltage circuit 206, high voltage circuit 208, and capacitive isolation barriers 210A and 210B on semiconductor substrate 280, level shifters 202a, 202b, 202c, and 202d in FIGS. 2A, 2B, 2C, and 2D, respectively, can achieve differential high speed level shifting through capacitive coupling using capacitive isolation barriers 210A and 210B, and high voltage level shifting through isolation structure 230, on a single piece of semiconductor substrate (e.g., semiconductor substrate 280). Furthermore, serializing two or more integrated capacitors in a single-chip configuration (e.g., capacitive isolation barriers 210A and 210B in FIG. 2A) can provide twice of the isolation voltage with the same thickness of the dielectric material in the capacitors in capacitive isolation barriers 210A and 210B.

In one implementation, capacitors C1a, C1b, C2a, and C2b in FIG. 2A, and capacitors C1 and C2 in FIGS. 2B, 2C and 2D can include on-chip metal to metal or on-chip poly to metal dielectric capacitors, having thick inter-metal dielectrics (e.g., oxide, polyimide or combination of the two) to withstand high voltages, to level shift signals from low voltage circuit 206 to high voltage circuit 208, which can be hundreds or thousands of voltage above ground G1. It should be understood that signal level shifting in each of level shifters 202a, 202b, 202c, and 202d can be bi-directional either from the outside of isolation structure 230 to the inside of isolation structure 230 or vice versa.

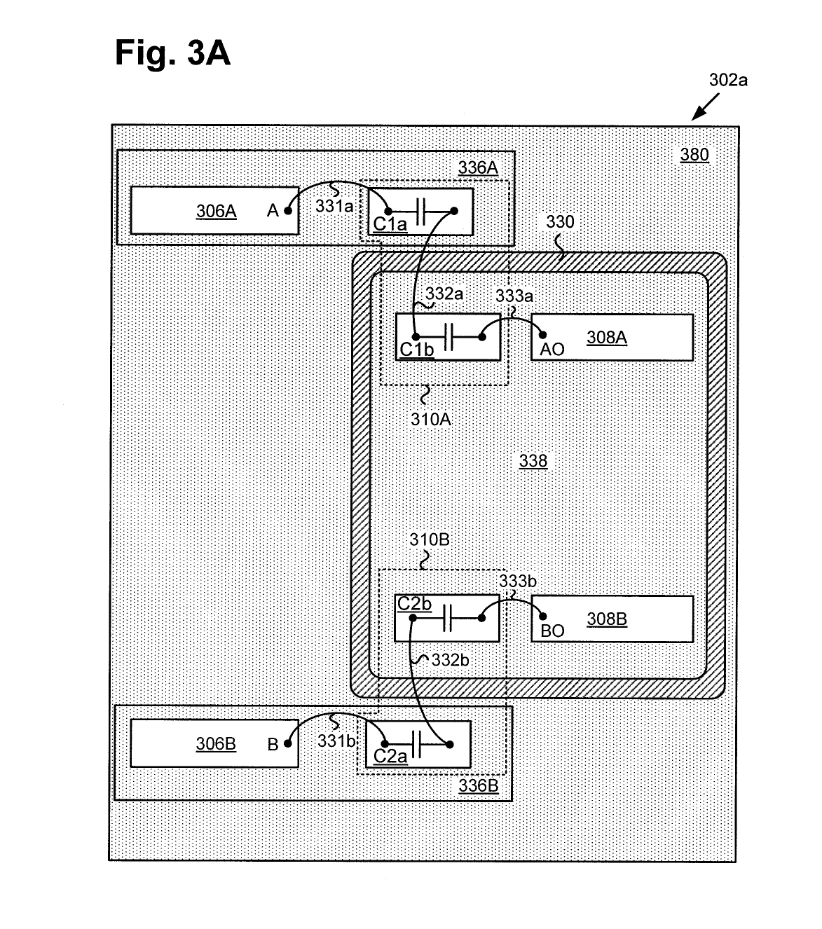

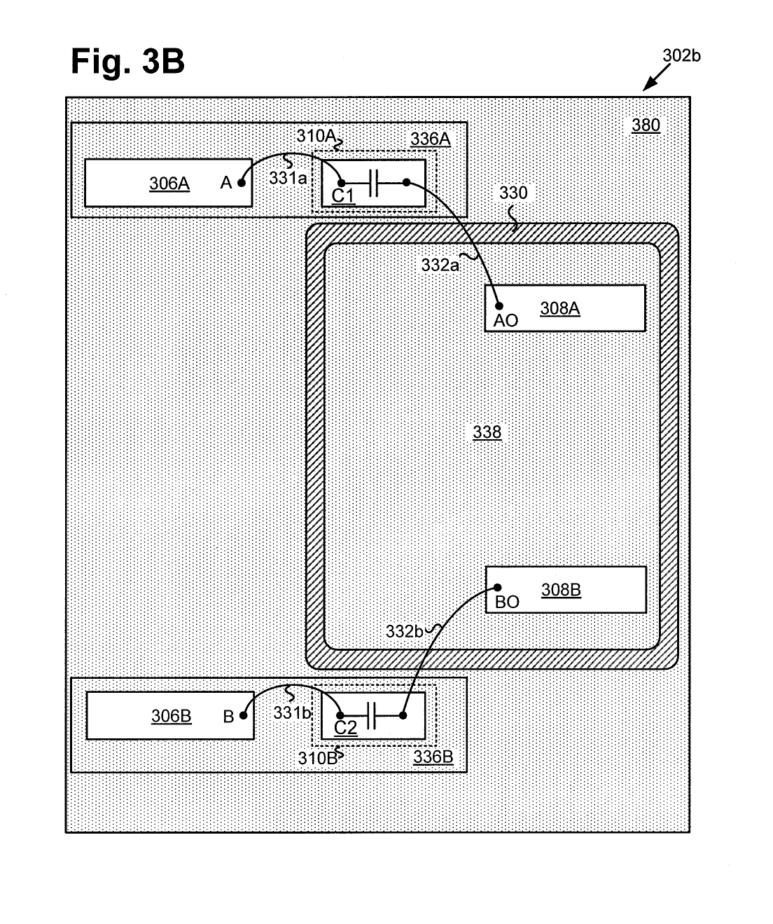

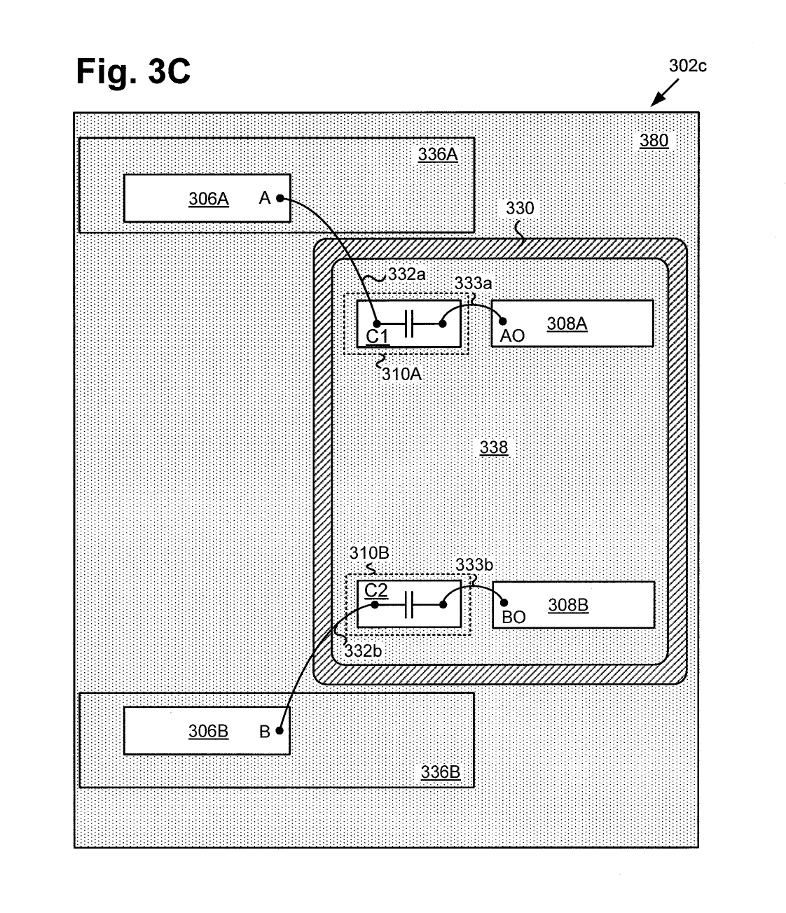

Turning to FIG. 3A, FIG. 3A illustrates a diagram of an exemplary single-chip level shifter having an isolation structure according to one implementation of the present application. In the present implementation, level shifter 302a is a single-chip level shifter, and may correspond to level shifter 202a in FIG. 2A. As illustrated in FIG. 3A, level shifter 302a includes low voltage circuit 306A in low voltage region 336A, low voltage circuit 306B in low voltage region 336B, high voltage circuits 308A and 308B in high voltage region 338, where low voltage regions 336A and 336B are monolithically integrated with high voltage region 338 in semiconductor substrate 380. High voltage region 338 is structurally isolated from low voltage regions 336A and 336B by isolation structure 330. Low voltage circuit 306A is electrically coupled to high voltage circuit 308A through capacitive isolation barrier 310A. Low voltage circuit 306B is electrically coupled to high voltage circuit 308B through capacitive isolation barrier 310B. Although not explicitly shown in FIG. 3A, it should be understood that low voltage circuits 306A and 306B of level shifter 302a are configured to receive an input signal (e.g., HI in FIG. 1A, 1B or 1C) in low voltage circuits 306A and 306B, while high voltage circuits 308A and 308B of level shifter 302a are configured to provide a level shifted output signal (e.g., HO in FIG. 1A, 1B or 1C).

In the present implementation, low voltage circuits 306A and 306B may separately or collectively correspond to low voltage circuit 106 in FIG. 1B or 1C, and high voltage circuits 308A and 308B may separately or collectively correspond to high voltage circuit 108 in FIG. 1B or 1C. Capacitive isolation barriers 310A and 310B may correspond respectively to capacitive isolation barriers 110A and 110B in FIG. 1B or 1C. Also, low voltage circuits 306A and 306B may separately or collectively correspond to low voltage circuit 206 in FIG. 2A, and high voltage circuits 308A and 308B may separately or collectively correspond to high voltage circuit 208 in FIG. 2A. Capacitive isolation barriers 310A and 310B may correspond respectively to capacitive isolation barriers 210A and 210B in FIG. 2A.

As illustrated in FIG. 3A, low voltage circuit 306A is in low voltage region 336A of semiconductor substrate 380, while low voltage circuit 306B is in low voltage region 336B of semiconductor substrate 380. High voltage circuits 308A and 308B are in high voltage region 338 of semiconductor substrate 380.

As illustrated in FIG. 3A, capacitive isolation barrier 310A includes capacitors C1a and C1b corresponding to capacitor C1 in FIG. 1B or 1C. Capacitor C1a of capacitive isolation barrier 310A is situated in low voltage region 336A and electrically coupled to low voltage circuit 306A by bond wire 331a. Capacitor C1b of capacitive isolation barrier 310A is situated in high voltage region 338 and electrically coupled to high voltage circuit 308A by bond wire 333a. As illustrated in FIG. 3A, capacitor C1a and capacitor C1b are structurally isolated by isolation structure 330, and electrically coupled to each other by bond wire 332a.

As illustrated in FIG. 3A, capacitive isolation barrier 310B includes capacitors C2a and C2b corresponding to capacitor C2 in FIG. 1B or 1C. Capacitor C2a of capacitive isolation barrier 310B is situated in low voltage region 336B and electrically coupled to low voltage circuit 306B by bond wire 331b. Capacitor C2b of capacitive isolation barrier 310B is situated in high voltage region 338 and electrically coupled to high voltage circuit 308B by bond wire 333b. As illustrated in FIG. 3A, capacitor C2a and capacitor C2b are structurally isolated by isolation structure 330, and electrically coupled to each other by bond wire 332b. Splitting up capacitive isolation barriers 310A and 310B by including capacitors in series can simplify manufacturing of capacitive isolation barriers 310A and 310B, amongst other advantages.

As illustrated in FIG. 3A, capacitor C1b of capacitive isolation barrier 310A, high voltage circuit 308A, capacitor C2b of capacitive isolation barrier 310B, and high voltage circuit 308B are situated in high voltage region 338, which is isolated from low voltage regions 336A and 336B by isolation structure 330. In the present implementation, isolation structure 330 forms an isolation ring substantially enclosing high voltage region 338 in semiconductor substrate 380. In one implementation, high voltage region 338 is a floating high voltage well formed by isolation structure 330 substantially enclosing high voltage region 338. Isolation structure 330 is configured to withstand a voltage difference of at least 600 volts between low voltage regions 336A and 336B and high voltage region 338. In one implementation, isolation structure 330 includes a junction termination structure. In another implementation, isolation structure 330 includes a reduced surface field (RESURF) structure. In yet another implementation, isolation structure 330 includes a deep trench structure.

In one implementation, semiconductor substrate 380 can include silicon, silicon-on-insulator (SOI), silicon-on-sapphire (SOS), silicon germanium, germanium, an epitaxial layer of silicon formed on a silicon substrate, or the like. In another implementation, semiconductor substrate 380 can include gallium nitride (GaN), GaN-on-insulator, or the like.

Turning to FIG. 3B, FIG. 3B illustrates a diagram of an exemplary single-chip level shifter having an isolation structure according to one implementation of the present application. In the present implementation, level shifter 302b is a single-chip level shifter, and may correspond to level shifter 202b in FIG. 2B. As illustrated in FIG. 3B, level shifter 302b includes low voltage circuit 306A in low voltage region 336A, low voltage circuit 306B in low voltage region 336B, high voltage circuits 308A and 308B in high voltage region 338, where low voltage regions 336A and 336B are monolithically integrated with high voltage region 338 in semiconductor substrate 380. High voltage region 338 is structurally isolated from low voltage regions 336A and 336B by isolation structure 330. Low voltage circuit 306A is electrically coupled to high voltage circuit 308A through capacitive isolation barrier 310A. Low voltage circuit 306B is electrically coupled to high voltage circuit 308B through capacitive isolation barrier 310B. Although not explicitly shown in FIG. 3B, it should be understood that low voltage circuits 306A and 306B of level shifter 302b are configured to receive an input signal (e.g., HI in FIG. 1A, 1B or 1C) in low voltage circuits 306A and 306B, while high voltage circuits 308A and 308B of level shifter 302b are configured to provide a level shifted output signal (e.g., HO in FIG. 1A, 1B or 1C).

In the present implementation, low voltage circuits 306A and 306B may separately or collectively correspond to low voltage circuit 106 in FIG. 1B or 1C, and high voltage circuits 308A and 308B may separately or collectively correspond to high voltage circuit 108 in FIG. 1B or 1C. Capacitive isolation barriers 310A and 310B may correspond respectively to capacitive isolation barriers 110A and 110B in FIG. 1B or 1C. Also, low voltage circuits 306A and 306B may separately or collectively correspond to low voltage circuit 206 in FIG. 2B, and high voltage circuits 308A and 308B may separately or collectively correspond to high voltage circuit 208 in FIG. 2B. Capacitive isolation barriers 310A and 310B may correspond respectively to capacitive isolation barriers 210A and 210B in FIG. 2B.

As illustrated in FIG. 3B, low voltage circuit 306A and capacitive isolation barrier 310A are in low voltage region 336A of semiconductor substrate 380, while low voltage circuit 306B and capacitive isolation barrier 310B are in low voltage region 336B of semiconductor substrate 380. High voltage circuits 308A and 308B are in high voltage region 338 of semiconductor substrate 380.

As illustrated in FIG. 3B, capacitive isolation barrier 310A includes capacitor C1 corresponding to capacitor C1 in FIG. 1B or 1C. Capacitor C1 of capacitive isolation barrier 310A is situated in low voltage region 336A and electrically coupled to low voltage circuit 306A by bond wire 331a. Capacitor C1 of capacitive isolation barrier 310A is electrically coupled to high voltage circuit 308A across isolation structure 330 by bond wire 332a.

As illustrated in FIG. 3B, capacitive isolation barrier 310B includes capacitor C2 corresponding to capacitor C2 in FIG. 1B or 1C. Capacitor C2 of capacitive isolation barrier 310B is situated in low voltage region 336B and electrically coupled to low voltage circuit 306B by bond wire 331b. Capacitor C2 of capacitive isolation barrier 310B is electrically coupled to high voltage circuit 308B across isolation structure 330 by bond wire 332b.

As illustrated in FIG. 3B, capacitor C1 of capacitive isolation barrier 310A and low voltage circuit 306A are situated in low voltage region 336A, which is structurally isolated from high voltage circuit 308A in high voltage region 338 by isolation structure 330. Capacitor C2 of capacitive isolation barrier 310B and low voltage circuit 306B are situated in low voltage region 336B, which is structurally isolated from high voltage circuit 308B in high voltage region 338 by isolation structure 330. In the present implementation, isolation structure 330 forms an isolation ring substantially enclosing high voltage region 338 in semiconductor substrate 380. In one implementation, high voltage region 338 is a floating high voltage well formed by isolation structure 330 substantially enclosing high voltage region 338. Isolation structure 330 is configured to withstand a voltage difference of at least 600 volts between low voltage regions 336A and 336B and high voltage region 338. In one implementation, isolation structure 330 includes a junction termination structure. In another implementation, isolation structure 330 includes a reduced surface field (RESURF) structure. In yet another implementation, isolation structure 330 includes a deep trench structure.

In one implementation, semiconductor substrate 380 can include silicon, silicon-on-insulator (SOI), silicon-on-sapphire (SOS), silicon germanium, germanium, an epitaxial layer of silicon formed on a silicon substrate, or the like. In another implementation, semiconductor substrate 380 can include gallium nitride (GaN), GaN-on-insulator, or the like.

Turning to FIG. 3C, FIG. 3C illustrates a diagram of an exemplary single-chip level shifter having an isolation structure according to one implementation of the present application. In the present implementation, level shifter 302c is a single-chip level shifter, and may correspond to level shifter 202c in FIG. 2C. As illustrated in FIG. 3C, level shifter 302c includes low voltage circuit 306A in low voltage region 336A, low voltage circuit 306B in low voltage region 336B, high voltage circuits 308A and 308B in high voltage region 338, where low voltage regions 336A and 336B are monolithically integrated with high voltage region 338 on semiconductor substrate 380. High voltage region 338 is structurally isolated from low voltage regions 336A and 336B by isolation structure 330. Low voltage circuit 306A is electrically coupled to high voltage circuit 308A through capacitive isolation barrier 310A. Low voltage circuit 306B is electrically coupled to high voltage circuit 308B through capacitive isolation barrier 310B. Although not explicitly shown in FIG. 3C, it should be understood that low voltage circuits 306A and 306B of level shifter 302c are configured to receive an input signal (e.g., HI in FIG. 1A, 1B or 1C) in low voltage circuits 306A and 306B, while high voltage circuits 308A and 308B of level shifter 302c are configured to provide a level shifted output signal (e.g., HO in FIG. 1A, 1B or 1C).

In the present implementation, low voltage circuits 306A and 306B may separately or collectively correspond to low voltage circuit 106 in FIG. 1B or 1C, and high voltage circuits 308A and 308B may separately or collectively correspond to high voltage circuit 108 in FIG. 1B or 1C. Capacitive isolation barriers 310A and 310B may correspond respectively to capacitive isolation barriers 110A and 110B in FIG. 1B or 1C. Also, low voltage circuits 306A and 306B may separately or collectively correspond to low voltage circuit 206 in FIG. 2C, and high voltage circuits 308A and 308B may separately or collectively correspond to high voltage circuit 208 in FIG. 2C. Capacitive isolation barriers 310A and 310B may correspond respectively to capacitive isolation barriers 210A and 210B in FIG. 2C.

As illustrated in FIG. 3C, low voltage circuit 306A is in low voltage region 336A of semiconductor substrate 380, while low voltage circuit 306B is in low voltage region 336B of semiconductor substrate 380. Capacitive isolation barriers 310A and 310B, and high voltage circuits 308A and 308B are in high voltage region 338 of semiconductor substrate 380.

As illustrated in FIG. 3C, capacitive isolation barrier 310A includes capacitor C1 corresponding to capacitor C1 in FIG. 1B or 1C. Capacitor C1 of capacitive isolation barrier 310A is situated in high voltage region 338 and electrically coupled to low voltage circuit 306A across isolation structure 330 by bond wire 332a. Also, capacitor C1 of capacitive isolation barrier 310A is electrically coupled to high voltage circuit 308A by bond wire 333a.

As illustrated in FIG. 3C, capacitive isolation barrier 310B includes capacitor C2 corresponding to capacitor C2 in FIG. 1B or 1C. Capacitor C2 of capacitive isolation barrier 310B is situated in high voltage region 338 and electrically coupled to low voltage circuit 306B across isolation structure 330 by bond wire 332b. Also, capacitor C2 of capacitive isolation barrier 310B is electrically coupled to high voltage circuit 308B by bond wire 333b.

As illustrated in FIG. 3C, capacitor C1 of capacitive isolation barrier 310A, high voltage circuit 308A, capacitor C2 of capacitive isolation barrier 310B, and high voltage circuit 308B are situated in high voltage region 338, which is structurally isolated from low voltage regions 336A and 336B by isolation structure 330. In the present implementation, isolation structure 330 forms an isolation ring substantially enclosing high voltage region 338 in semiconductor substrate 380. In one implementation, high voltage region 338 is a floating high voltage well formed by isolation structure 330 substantially enclosing high voltage region 338. Isolation structure 330 is configured to withstand a voltage difference of at least 600 volts between low voltage regions 336A and 336B and high voltage region 338. In one implementation, isolation structure 330 includes a junction termination structure. In another implementation, isolation structure 330 includes a reduced surface field (RESURF) structure. In yet another implementation, isolation structure 330 includes a deep trench structure.

In one implementation, semiconductor substrate 380 can include silicon, silicon-on-insulator (SOI), silicon-on-sapphire (SOS), silicon germanium, germanium, an epitaxial layer of silicon formed on a silicon substrate, or the like. In another implementation, semiconductor substrate 380 can include gallium nitride (GaN), GaN-on-insulator, or the like.

It should be understood that, although not explicitly shown in FIGS. 3A, 3B and 3C, a level shifter may include capacitive isolation barriers completely in an isolation barrier region of semiconductor substrate 380, that is outside of low voltage regions 336A and 336B, and high voltage region 338.

Thus, as described above with respect to FIGS. 1A, 1B, 1C, 2A, 2B, 2C, 2D, 3A, 3B and 3C, various implementations of the present application provide for single-chip level shifters having a low voltage circuit in a low voltage region electrically coupled to a high voltage circuit in a high voltage region through one or more capacitive isolation barriers, which are monolithically integrated on a single piece of semiconductor substrate. The one or more capacitive isolation barriers allows for high speed level shifting. In addition, the low voltage region and the high voltage region are structurally isolated by an isolation structure to allow the level shifter to perform high voltage level shifting on the single piece of semiconductor substrate. The level shifters according to various implementations of the present application provide a single-chip package solution to achieve CMT dv/dt immunity, reduce propagation delay, and lower power dissipation.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A semiconductor device comprising:
a low voltage region in a semiconductor substrate;
a high voltage region monolithically integrated with said low voltage region in said semiconductor substrate;
wherein said low voltage region is electrically coupled to said high voltage region through a capacitive isolation barrier;
wherein said high voltage region is structurally isolated from said low voltage region by an isolation structure.

2. The semiconductor device of claim 1, wherein said isolation structure includes a junction termination structure.

3. The semiconductor device of claim 1, wherein said isolation structure includes a deep trench structure.

4. The semiconductor device of claim 1, wherein said isolation structure includes a reduced surface field (RESURF) structure.

5. The semiconductor device of claim 1, wherein said isolation structure forms an isolation ring substantially enclosing said high voltage region in said semiconductor substrate.

6. The semiconductor device of claim 1, wherein said low voltage region includes a low voltage circuit of a level shifter.

7. The semiconductor device of claim 1, wherein said high voltage region includes a high voltage circuit of a level shifter.

8. The semiconductor device of claim 1, wherein said low voltage region is configured to provide a differential signal to said high voltage region through said capacitive isolation barrier.

9. The semiconductor device of claim 1, wherein said high voltage region is configured to receive a differential signal from said low voltage region through said capacitive isolation barrier so as to level shift said differential signal.

10. The level shifter of claim 1, wherein said semiconductor substrate is selected from the group consisting of a silicon substrate, a silicon-on-insulator substrate, and a gallium nitride (GaN)-on-silicon substrate.

11. An integrated circuit comprising:
a low voltage circuit in a low voltage region of a semiconductor substrate;
a high voltage circuit in a high voltage region in said semiconductor substrate;
wherein said low voltage region is electrically coupled to said high voltage region through a capacitive isolation barrier;
wherein said high voltage region is structurally isolated from said low voltage region by an isolation structure.

12. The integrated circuit of claim 11, wherein said isolation structure includes a junction isolation termination structure.

13. The integrated circuit of claim 11, wherein said isolation structure includes a deep trench isolation structure.

14. The integrated circuit of claim 11, wherein said isolation structure includes a reduced surface field (RESURF) isolation structure.

15. The integrated circuit of claim 11, wherein said isolation structure forms an isolation ring substantially enclosing said high voltage circuit in said semiconductor substrate.

16. The integrated circuit of claim 11, wherein said low voltage circuit and said high voltage circuit form a level shifter.

17. The integrated circuit of claim 11, wherein said low voltage circuit and said high voltage circuit are monolithically integrated in said semiconductor substrate.

18. The integrated circuit of claim 11, wherein said low voltage circuit is configured to provide a differential signal to said high voltage circuit through said capacitive isolation barrier.

19. The integrated circuit of claim 11, wherein said high voltage circuit is configured to receive a differential signal from said low voltage circuit through said capacitive isolation barrier so as to level shift said differential signal.

20. The integrated circuit of claim 11, wherein said semiconductor substrate is selected from the group consisting of a silicon substrate, a silicon-on-insulator substrate, and a gallium nitride (GaN)-on-silicon substrate.
